(19) United States
(12) Patent Application Publication
(10) Pub. No.: US 2024/0221983 A1
(43) Pub. Date: Jul. 4, 2024

(54) Non-Inductive Coil Assembly

(71) Applicant: Siemens Healthcare Limited, Camberley (GB)

(72) Inventors: Yu Xin Nie, Shenzhen (CN); Jianping He, Shenzhen (CN); Bin He, Shenzhen (CN); Jun Zhao Wu, Shenzen (CN)

(73) Assignee: Siemens Healthcare Limited, Camberley (GB)

(21) Appl. No.: 18/399,832

(22) Filed: Dec. 29, 2023

(30) Foreign Application Priority Data
Dec. 30, 2022 (CN) 202211725707.X

(51) Int. Cl. H01F 6/06

(52) U.S. Cl. CPC H01F 6/06

(57) ABSTRACT

A non-inductive coil assembly, including: a superconducting joint configured to be conductive; and a superconducting coil comprising an even number of conducting wires helically wound together, wherein a first end of the superconducting coil is connected to the superconducting joint, and, at a second end of the superconducting coil, the even number of conducting wires divide into two strands and are respectively helically wound to form an input group and an output group, the numbers of conducting wires of the input group and the output group are the same, and current is flowable to the superconducting joint via the conducting wire corresponding to the input group, and flowable out of the superconducting coil from the conducting wire corresponding to the output group.

### TECHNICAL FIELD

The present disclosure relates to the technical field of superconductors, and especially to a non-inductive coil assembly and a manufacturing method therefor.

### BACKGROUND

Superconducting magnets are widely used in MRI systems because they may provide a strong magnetic field with high stability. A superconducting switch is an important component; it is connected in parallel to two ends of a superconducting coil to achieve closed-loop motion of current in a superconducting magnet. A superconducting switch has two working states: a normal state (resistance state) and a superconducting state (no-resistance state). Before increasing/reducing magnet current, the superconducting switch is driven to the normal state by a heater. After the required current is reached, the heater is turned off, and the superconducting switch changes to the superconducting state, causing current to pass through without resistance.

The superconducting switch is generally formed by winding multiple twisted strands of superconducting wire. In order to reduce a reactance effect thereof on a circuit and environment as much as possible, the conducting wire in the switch should be wound into a non-inductive coil. The key to manufacturing a superconducting switch is to use a winding method for a non-inductive coil with stable performance.

A mainstream method for winding a non-inductive superconducting switch is a “dual-wire winding method.” Patent CN1056245C and patent CN102394269A both disclose a non-inductive coil winding method; as shown in FIG. 1, a superconducting wire rod 20 is bent by 180 degrees at a midpoint in the length thereof, and, in order to prevent the superconducting wire rod from being damaged at a fold 201, the folded radius cannot be too small; next, two half superconducting wire rods are wound on a winding frame by the same number of turns. In the winding process, the tension and speed of the two half superconducting wire rods should be kept the same. After winding, two ends of the multi-strand conducting wire come out from the coil at the same place. This type of dual-wire winding coil may be seen as a combination of two sub-coils wound in opposite directions. When current is input from one end and output from the other end, the directions of the current in the two sub-coils are exactly opposite each other, thereby achieving non-inductance in the overall coil.

However, a non-inductive coil made using the above-mentioned dual-wire winding method is not completely non-inductive because the current input conducting wire and output conducting wire in the coil do not fully coincide with each other spatially; the position in space of one sub-coil of the two sub-coils is displaced with respect to the other. Moreover, the conducting wire of a folded region also does not coincide significantly in space. These factors result in a dual-wire winding superconducting switch having a small inductance, which produces a negative effect on a circuit and environment.

In addition, at a midpoint, the superconducting wire is bent by 180 degrees, which also causes the superconducting wire to easily break at the wire-bending point. Moreover, controlling the dual-wire winding process is difficult, it is difficult to keep the tension values of the two conducting wires the same at any given time, and fluctuations in tension in the conducting wires reduce the stability of the superconducting switch in operation.

### SUMMARY

The technical problem to be solved by the present disclosure is to provide a non-inductive coil assembly and manufacturing method; therefore, in order to overcome the defect of a non-inductive coil in the prior art, easily generating inductance, producing an undesirable effect on a circuit and environment.

The present disclosure achieves the above-mentioned technical effects by means of the following technical solutions:

The present disclosure provides a non-inductive coil assembly, the non-inductive coil assembly comprising:
a superconducting joint, the superconducting joint configured to be conductive; and
a superconducting coil, the superconducting coil comprising an even number of conducting wires, the even number of conducting wires being helically wound together, a first end of the superconducting coil being connected to the superconducting joint, and, at a second end of the superconducting coil, the even number of conducting wires dividing into two strands and being respectively helically wound to form an input group and an output group, the numbers of conducting wires of the input group and the output group being the same, and current flowing to the superconducting joint via the conducting wire corresponding to the input group, and flowing out of the superconducting coil from the conducting wire corresponding to the output group.

In the present solution, one half of the conducting wire in the superconducting coil corresponds to the input group, the direction of current flows from the input group to the superconducting joint, the other half of the conducting wire in the superconducting coil corresponds to the output group, the direction of current flows from the superconducting joint to the output group, and the directions of current of the two are opposite each other. Thus, the superconducting coil as a whole may be seen as a combination of two sub-coils wound in opposite directions, such that the overall superconducting coil is non-inductive. In this type of innovative superconducting coil of the present solution, two parts of conducting wire, in which the directions of current are opposite each other, are helically wound together to form a coil. An amount of displacement of position in space between the two conducting wires, in which the directions of current are opposite each other, is relatively small, causing a reactance effect of the superconducting switch on a circuit and environment to be minimal. In addition, the present solution replaces a conducting wire folded part of a “dual-wire winding method” with the superconducting joint so that an amount of inductance of a bent region is thereby eliminated, and the superconducting wire can also be prevented from breaking at the fold. Moreover, in the present solution, because only one whole superconducting coil is wound, compared with the “dual-wire winding method,” the winding process of the present disclosure is simpler, the tension of the wire is also easier to control, and this increases the stability of the superconducting switch when operating.

Preferably, the superconducting joint is configured such that the resistance of the superconducting joint is zero when the temperature reduces to a threshold value.

In the present solution, the superconducting joint being provided with the above property can realize a superconducting connection between the superconducting coil and the superconducting joint, and, in a low-temperature situation, resistance at the superconducting joint is zero, which prevents the superconducting joint from influencing the operating performance of the superconducting switch in a no-resistance state.

Preferably, the non-inductive coil assembly comprises a cylindrical winding frame, the superconducting coil is wound on an outer wall face of the winding frame, and the superconducting joint is connected to the winding frame.

In the present solution, using the above structural configuration, the structure is simple, which facilitates manufacturing.

Preferably, the winding frame is provided with an accommodating slot, and the superconducting joint is clamped in the accommodating slot.

In the present solution, by means of providing the accommodating slot, the superconducting joint can be fixed. At the same time, the superconducting joint is prevented from affecting the arrangement of the superconducting coil on the winding frame.

Preferably, two end faces of the winding frame are provided with a winding end plate, the winding end plate is provided with an accommodating slot, and the superconducting joint is clamped in the accommodating slot.

In the present solution, by means of providing the winding end plates, the superconducting coil can be prevented from coming off two ends of the winding frame; the accommodating slot is arranged on the winding end plate and does not affect the winding of the superconducting coil on the winding frame.

Preferably, after the superconducting joint is heated to melting point and becomes liquid, the first end of the superconducting coil is inserted inside the superconducting joint of a liquid state, and thereafter, reducing the temperature causes the superconducting joint to change to a solid state, to cause the superconducting coil to fix to the superconducting joint.

In the present solution, using the above structural form, while the superconducting coil is fixed to the superconducting joint, current can flow from the conducting wire corresponding to the input group into the conducting wire corresponding to the output group by means of the superconducting joint.

Preferably, the superconducting joint is cylindrical.

Preferably, the material of the superconducting joint is a lead bismuth alloy.

In the present solution, the melting point of the lead bismuth alloy is low, convenient for heating same to a liquid state, so that the processing efficiency of the superconducting joint is high; in addition, the resistivity of the lead bismuth alloy decreases sharply under the effect of a magnetic field, convenient for causing the resistance of the superconducting joint to be zero at a low temperature, thereby realizing a superconducting connection between the superconducting joint and the superconducting coil.

The present disclosure further provides a manufacturing method for a non-inductive coil assembly, the method being used for manufacturing the non-inductive coil assembly described above, and the manufacturing method comprising the following steps:
S1, helically winding the even number of conducting wires together to form the superconducting coil;
S2, fixing a first end of the superconducting coil to the superconducting joint; and
S3, at a second end of the superconducting coil, dividing the superconducting coil into two strands of the same number of conducting wires and respectively helically winding the strands to form an input group and an output group, wherein when the superconducting coil is energized, current flows from the input group to the output group.

In a present solution, one half of the conducting wire in the superconducting coil corresponds to the input group, the direction of current flows from the input group to the superconducting joint, the other half of the conducting wire in the superconducting coil corresponds to the output group, the direction of current flows from the superconducting joint to the output group, and the directions of current of the two are opposite each other. Thus, the superconducting coil as a whole may be seen as a combination of two sub-coils wound in opposite directions, such that the overall superconducting coil is non-inductive. In this type of innovative superconducting coil of the present solution, two parts of conducting wire, in which the directions of current are opposite each other, are helically wound together to form a coil. An amount of displacement of position in space between the two conducting wires, in which the directions of current are opposite each other, is relatively small, causing a reactance effect of the superconducting switch on a circuit and environment to be minimal. In addition, the present solution replaces a conducting wire folded part of a “dual-wire winding method” with the superconducting joint so that an amount of inductance of a bent region is thereby eliminated, and the superconducting wire can also be prevented from breaking at the fold. Moreover, in the present solution, because only one whole superconducting coil is wound, compared with the “dual-wire winding method,” the winding process of the present disclosure is simpler, the tension of the wire is also easier to control, and this increases the stability of the superconducting switch when operating.

Preferably, the non-inductive coil assembly further comprises a cylindrical winding frame, and the following steps are further comprised between step S2 and step S3:
S21, fixing the superconducting joint to the winding frame; and
S22, winding the superconducting coil on the winding frame.

On the basis that common knowledge in the art is conformed to, the above preferred conditions may be combined in any way to obtain preferred examples of the present utility model.

A positive, further effect of the present disclosure lies in: regarding the non-inductive coil assembly, one half of the conducting wire in the superconducting coil corresponds to the input group, the direction of current flows from the input group to the superconducting joint, the other half of the conducting wire in the superconducting coil corresponds to the output group, the direction of current flows from the superconducting joint to the output group, and the directions of current of the two are opposite each other, and thus, the superconducting coil as a whole may be seen as a combination of two sub-coils wound in opposite directions, such that the overall superconducting coil is non-inductive. In this type of innovative superconducting coil of the present solution, two parts of conducting wire, in which the directions of current are opposite each other, are helically wound together to form a coil. An amount of displacement of position in space between the two conducting wires, in which the directions of current are opposite each other, is relatively small, causing a reactance effect of the superconducting switch on a circuit and environment to be minimal. In addition, the present solution replaces a conducting wire folded part of a “dual-wire winding method” with the superconducting joint so that an amount of inductance of a bent region is thereby eliminated, and the superconducting wire can also be prevented from breaking at the fold. Moreover, in the present solution, because only one whole superconducting coil is wound, compared with the “dual-wire winding method,” the winding process of the present disclosure is simpler, the tension of the wire is also easier to control, and this increases the stability of the superconducting switch when operating.

### BRIEF DESCRIPTION OF THE DRAWINGS

Embodiments of the present disclosure are described in detail below with reference to the accompanying drawings to give those skilled in the art a clearer understanding of the abovementioned and other features and advantages of the present disclosure. Drawings:

FIG. 1 is a three-dimensional schematic structural diagram of a non-inductive superconducting switch in the background art.

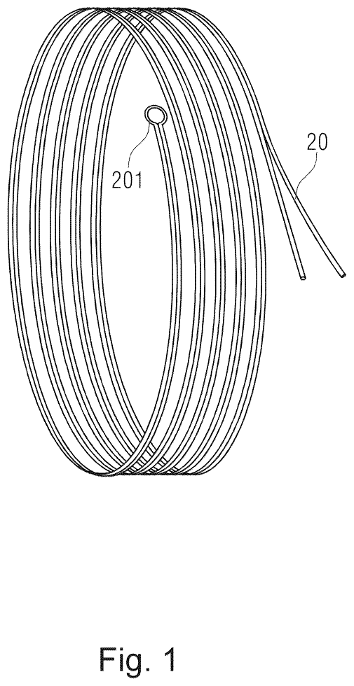

FIG. 2 is a three-dimensional schematic structural diagram of a non-inductive coil assembly according to a preferred embodiment of the present disclosure, wherein a helical winding manner of conducting wire is not shown.

FIG. 3 is a three-dimensional schematic structural diagram of a superconducting joint according to a preferred embodiment of the present disclosure.

FIG. 4 is a sectional view of a superconducting coil according to a preferred embodiment of the present disclosure.

In Background Art, the reference labels are as follows:
Superconducting wire rod 20
Fold 201

In the present disclosure, the reference labels are as follows:
Non-inductive coil assembly 100
Superconducting joint 101
Superconducting coil 102
Input group 103
Output group 104

### DETAILED DESCRIPTION

To enable a clearer understanding of the technical features, objectives, and effects of the present disclosure, particular embodiments of the present disclosure are now explained with reference to the accompanying drawings, in which identical labels indicate identical parts.

As used herein, “schematic” means “serving as an instance, example or illustration.” No drawing or embodiment described herein as “schematic” should be interpreted as being a more preferred or more advantageous technical solution.

To make the drawings appear uncluttered, only those parts relevant to the present disclosure are shown schematically in the drawings; they do not represent the actual structure thereof as a product. Furthermore, to make the drawings appear uncluttered for ease of understanding, in the case of components having the same structure or function in certain drawings, only one of these is drawn schematically, or only one is marked.

In this text, “a” does not only mean “just this one”; it may also mean “more than one.” As used herein, “first” and “second,” etc., are merely used to differentiate between parts, not to indicate their order or degree of importance, or any precondition of mutual existence, etc.

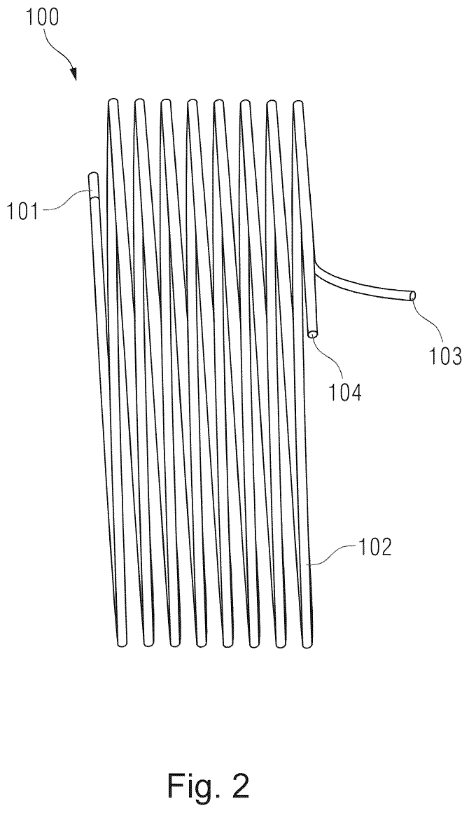

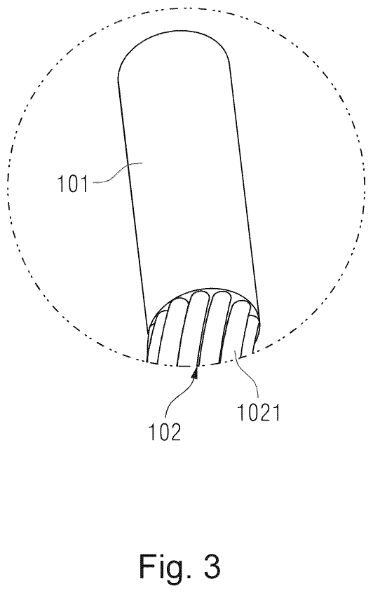

The present embodiment presents a non-inductive coil assembly 100. As shown in FIGS. 2-4, the non-inductive coil assembly 100 comprises a superconducting joint 101 and a superconducting coil 102; the superconducting joint 101 is configured to be conductive. The superconducting coil 102 comprising an even number of conducting wires, the even number of conducting wires being helically wound together, a first end of the superconducting coil 102 being connected to the superconducting joint 101, and, at a second end of the superconducting coil 102, the even number of conducting wires dividing into two strands and being respectively helically wound to form an input group 103 and an output group 104, the numbers of conducting wires of the input group 103 and the output group 104 being the same, and current flowing to the superconducting joint 101 via the conducting wire corresponding to the input group 103, and flowing out of the superconducting coil 102 from the conducting wire corresponding to the output group 104.

In the present embodiment, one half of the conducting wire in the superconducting coil 102 corresponds to the input group 103, the direction of current flows from the input group 103 to the superconducting joint 101, the other half of the conducting wire in the superconducting coil 102 corresponds to the output group 104, the direction of current flows from the superconducting joint 101 to the output group 104, and the directions of current of the two are opposite each other. Thus, the superconducting coil 102 as a whole may be seen as a combination of two sub-coils wound in opposite directions, such that the overall superconducting coil 102 is non-inductive. In this type of innovative superconducting coil 102 of the present embodiment, two parts of conducting wire, in which the directions of current are opposite each other, are helically wound together to form a coil. An amount of displacement of position in space between the two conducting wires, in which the directions of current are opposite each other, is relatively small, causing a reactance effect of the superconducting switch on a circuit and environment to be minimal. In addition, the present solution replaces a conducting wire folded part of a “dual-wire winding method” with the superconducting joint 101 so that an amount of inductance of a bent region is thereby eliminated, and the superconducting wire can also be prevented from breaking at the fold. Moreover, in the present embodiment, because only one whole superconducting coil 102 is wound, compared with the “dual-wire winding method,” the winding process of the present disclosure is simpler, the tension of the wire is also easier to control, and this increases the stability of the superconducting switch when operating.

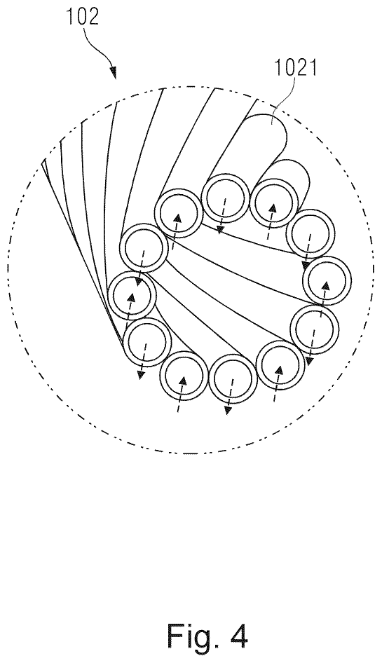

It must be explained that an even number of conducting wires in the superconducting coil 102 are helically wound to form a single strand of twisted conducting wire. The even number of conducting wires may be randomly divided into two strands at the second end, just as long as the two strands are allotted the same number of conducting wires. As shown in FIG. 4, in a preferred embodiment, when an even number of conducting wires are divided into two strands, an interweaving allotting means is used; that is, two conducting wires that are adjacent respectively diverge into the input group 103 and the output group 104. Such a configuration causes the directions of current of the two conducting wires, which are adjacent to be opposite each other, thereby minimising the amount of displacement of position in space.

The superconducting joint 101 is configured such that resistance of the superconducting joint 101 is zero when the temperature reduces to a threshold value. The superconducting joint 101 being provided with the above property can realize a superconducting connection between the superconducting coil 102 and the superconducting joint 101, and, in a low temperature situation, resistance at the superconducting joint 101 is zero, which prevents the superconducting joint 101 from influencing the operating performance of the superconducting switch in a no-resistance state.

The non-inductive coil assembly 100 comprises a cylindrical winding frame, the superconducting coil 102 is wound on an outer wall face of the winding frame, and the superconducting joint 101 is connected to the winding frame. Using the above structural configuration, the structure is simple, which facilitates manufacturing.

The winding frame is provided with an accommodating slot, and the superconducting joint 101 is clamped in the accommodating slot. By means of providing the accommodating slot, the superconducting joint 101 can be fixed. At the same time, the superconducting joint 101 is prevented from affecting the arrangement of the superconducting coil 102 on the winding frame. In an alternative embodiment, other means may be used to fix the superconducting joint 101, for example, bonding, ultrasonic welding, etc. Specifically, the shape of the accommodating slot matches the shape of the superconducting joint 101.

It must be explained that, in other alternative embodiments, the superconducting joint 101 also may be fixed at another position. For example, two end faces of the winding frame are provided with a winding end plate, the winding end plate is provided with an accommodating slot, and the superconducting joint 101 is clamped in the accommodating slot. By means of providing the winding end plates, the superconducting coil 102 can be prevented from coming off two ends of the winding frame; the accommodating slot is arranged on the winding end plate and does not affect the winding of the superconducting coil 102 on the winding frame.

After the superconducting joint 101 is heated to melting point and becomes liquid, the first end of the superconducting coil 102 is inserted inside the superconducting joint 101 of a liquid state, and thereafter, reducing the temperature causes the superconducting joint 101 to change to a solid state, to cause the superconducting coil 102 to fix to the superconducting joint 101. Using the above structural form, while the superconducting coil 102 is fixed to the superconducting joint 101, current can flow from the conducting wire corresponding to the input group 103 into the conducting wire corresponding to the output group 104 by means of the superconducting joint 101. Specifically, when the superconducting joint 101 is manufactured, a mold of a corresponding shape may be provided, the liquid superconducting joint 101 is poured into the mold, and then a first end of the superconducting coil 102 is inserted in the mold. After solidification, the superconducting joint 101 and superconducting coil 102, which are fixed together, are taken out from the mold.

In the present embodiment, the superconducting joint 101 is cylindrical. In another alternative embodiment, the superconducting joint 101 may be another shape, such as a prism, cube, cuboid, or other shape.

The material of the superconducting joint 101 is a lead bismuth alloy. The melting point of the lead bismuth alloy is low, convenient for heating same to a liquid state so that the processing efficiency of the superconducting joint 101 is high; in addition, the resistivity of the lead bismuth alloy decreases sharply under the effect of a magnetic field, convenient for causing the resistance of the superconducting joint 101 to be zero at a low temperature, thereby realizing a superconducting connection between the superconducting joint 101 and the superconducting coil 102. In an alternative embodiment, another bismuth alloy may be used, such as a tin bismuth alloy, as long as the above-mentioned effect can be achieved.

The present embodiment further provides a manufacturing method for a non-inductive coil assembly 100, the method being used for manufacturing the non-inductive coil assembly 100 described above, and the manufacturing method comprising the following steps:
S1, helically winding an even number of conducting wires together to form the superconducting coil 102;
S2, fixing a first end of the superconducting coil 102 to the superconducting joint 101; and
S3, at a second end of the superconducting coil 102, dividing the superconducting coil 102 into two strands of the same number of conducting wires, and respectively helically winding the strands to form an input group 103 and an output group 104, wherein when the superconducting coil 102 is energized, current flows from the input group 103 to the output group 104.

In the present embodiment, one half of the conducting wire in the superconducting coil 102 corresponds to the input group 103, the direction of current flows from the input group 103 to the superconducting joint 101, the other half of the conducting wire in the superconducting coil 102 corresponds to the output group 104, the direction of current flows from the superconducting joint 101 to the output group 104, and the directions of current of the two are opposite each other. Thus, the superconducting coil 102 as a whole may be seen as a combination of two sub-coils wound in opposite directions, such that the overall superconducting coil 102 is non-inductive. In this type of innovative superconducting coil 102 of the present solution, two parts of conducting wire, in which the directions of current are opposite each other, are helically wound together to form a coil. An amount of displacement of position in space between the two conducting wires, in which the directions of current are opposite each other, is relatively small, causing a reactance effect of the superconducting switch on a circuit and environment to be minimal. In addition, the present solution replaces a conducting wire folded part of a “dual-wire winding method” with the superconducting joint 101 so that an amount of inductance of a bent region is thereby eliminated, and the superconducting wire can also be prevented from breaking at the fold. Moreover, in the present solution, because only one whole superconducting coil 102 is wound, compared with the “dual-wire winding method,” the winding process of the present disclosure is simpler, the tension of the wire is also easier to control, and this increases the stability of the superconducting switch when operating.

It must be explained that the order of the above steps is not fixed; for example, the order may also proceed S1, S3, S2.

The non-inductive coil assembly 100 further comprises a cylindrical winding frame, and the following steps are further comprised between step S2 and step S3:
S21, fixing the superconducting joint 101 to the winding frame; and
S22, winding the superconducting coil 102 on the winding frame.

The above are merely embodiments of the present disclosure and are not intended to limit it. Any modifications, equivalent substitutions or improvements, etc., made within the spirit and principles of the present disclosure shall be included in the scope of protection thereof. Although particular embodiments of the present disclosure are described above, those skilled in the art should understand that this is merely an exemplary explanation, and the scope of protection of the present disclosure is defined by the attached claims. Those skilled in the art may make various changes or modifications to these embodiments without departing from the principles and essence of the present disclosure. Still, these changes and modifications all fall within the scope of protection of the present disclosure.

1. A non-inductive coil assembly, comprising:
a superconducting joint configured to be conductive; and
a superconducting coil comprising an even number of conducting wires helically wound together, wherein a first end of the superconducting coil is connected to the superconducting joint, and, at a second end of the superconducting coil, the even number of conducting wires divide into two strands and are respectively helically wound to form an input group and an output group, the numbers of conducting wires of the input group and the output group are the same, and current is flowable to the superconducting joint via the conducting wire corresponding to the input group, and flowable out of the superconducting coil from the conducting wire corresponding to the output group.

2. The non-inductive coil assembly of claim 1, wherein the superconducting joint is configured such that resistance of the superconducting joint is zero when temperature reduces to a threshold value.

3. The non-inductive coil assembly of claim 1, further comprising:
a cylindrical winding frame,
wherein the superconducting coil is wound on an outer wall face of the winding frame, and the superconducting joint is connected to the winding frame.

4. The non-inductive coil assembly of claim 3, wherein the winding frame is provided with an accommodating slot, and the superconducting joint is clamped in the accommodating slot.

5. The non-inductive coil assembly of claim 3, wherein two end faces of the winding frame are provided with a winding end plate, the winding end plate is provided with an accommodating slot, and the superconducting joint is clamped in the accommodating slot.

6. The non-inductive coil assembly of claim 1, wherein after the superconducting joint is heated to melting point and becomes liquid, the first end of the superconducting coil is inserted inside the superconducting joint of a liquid state, and thereafter, reducing temperature causes the superconducting joint to change to a solid state, to cause the superconducting coil to fix to the superconducting joint.

7. The non-inductive coil assembly of claim 1, wherein the superconducting joint is cylindrical.

8. The non-inductive coil assembly of claim 1, wherein a material of the superconducting joint is a lead bismuth alloy.

9. A method of manufacturing the non-inductive coil assembly of claim 1, comprising:
S1, helically winding the even number of conducting wires together to form the superconducting coil;
S2, fixing a first end of the superconducting coil to the superconducting joint; and
S3, at a second end of the superconducting coil, dividing the superconducting coil into two strands of the same number of conducting wires, and respectively helically winding the strands into an input group and an output group, wherein when the superconducting coil is energized, current flows from the input group to the output group.

10. The method of claim 9, wherein the non-inductive coil assembly further comprises a cylindrical winding frame, and the method further comprises, between step S2 and step S3:
S21, fixing the superconducting joint to the winding frame; and
S22, winding the superconducting coil on the winding frame.
